(19) United States
(12) Patent Application Publication
(10) Pub. No.: US 2021/0240079 A1
(43) Pub. Date: Aug. 5, 2021

(54) PHOTORESIST COMPOSITION, PHOTOLITHOGRAPHY METHOD USING THE SAME, AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Juhyeon PARK, Suwon-si (KR); Su Min KIM, Suwon-si (KR); Yechan KIM, Hwaseong-si (KR); Ju-Young KIM, Seoul (KR); Jinjoo KIM, Seoul (KR); Hyunwoo KIM, Seongnam-si (KR); Hyunji SONG, Suwon-si (KR); Songse YI, Seoul (KR); Suk Koo HONG, Suwon-si (KR)

(21) Appl. No.: 17/003,373

(22) Filed: Aug. 26, 2020

(30) Foreign Application Priority Data
Feb. 4, 2020 (KR) 10-2020-0013150

(51) Int. Cl. G03F 7/038; G03F 7/004; G03F 7/38; H01L 21/027; H01L 21/3213; G03F 7/20

(52) U.S. Cl. CPC G03F 7/038; G03F 7/0045; G03F 7/38; C08L 25/14; H01L 21/32139; G03F 7/2004; H01L 21/0275

(57) ABSTRACT

A photolithography method and a method of manufacturing a semiconductor device, the photolithography method including applying a composition on a substrate to form a photoresist layer; performing an exposing process using extreme ultraviolet radiation (EUV) on the photoresist layer; and developing the photoresist layer to form photoresist patterns, wherein the composition includes a photosensitive resin, a photo-acid generator, a photo decomposable quencher, an additive, and a solvent, and the additive is a compound represented by the following Formula 4A:

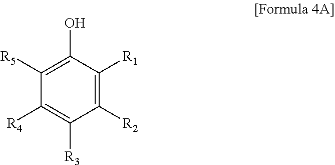

in Formula 4A, R₁ to R₅ are each independently hydrogen or iodine, at least one of R₁ to R₅ being iodine.

### CROSS-REFERENCE TO RELATED APPLICATION

Korean Patent Application No. 10-2020-0013150, filed on Feb. 4, 2020, in the Korean Intellectual Property Office, and entitled: “Photoresist Composition, Photolithography Method Using the Same, and Method of Manufacturing Semiconductor Device Using the Same,” is incorporated by reference herein in its entirety.

### BACKGROUND

### 1. Field

Embodiments relate to a photoresist composition, a photolithography method using the same, and a method of manufacturing semiconductor device using the same.

### 2. Description of the Related Art

In order to fulfill excellent performance and low costs for consumers, the increase of integration degree and the improvement of reliability of semiconductor devices are required.

### SUMMARY

The embodiments may be realized by providing a photolithography method including applying a composition on a substrate to form a photoresist layer; performing an exposing process using extreme ultraviolet radiation (EUV) on the photoresist layer; and developing the photoresist layer to form photoresist patterns, wherein the composition includes a photosensitive resin, a photo-acid generator, a photo decomposable quencher, an additive, and a solvent, and the additive is a compound represented by the following Formula 4A:

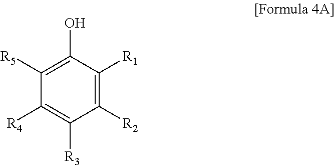

in Formula 4A, R₁ to R₅ are each independently hydrogen or iodine, at least one of R₁ to R₅ being iodine.

The embodiments may be realized by providing a method of manufacturing a semiconductor device, the method including forming a target layer on a substrate; applying a composition on the target layer to form a photoresist layer; performing an exposing process using extreme ultraviolet radiation (EUV) on the photoresist layer; developing the photoresist layer to form photoresist patterns; and performing an etching process for patterning the target layer using the photoresist patterns as a mask, wherein the composition includes a compound represented by the following Formula 4A as an additive,

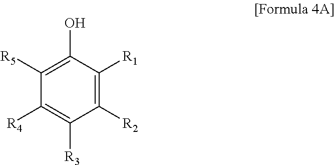

in Formula 4A, R₁ to R₅ are each independently hydrogen or iodine, at least one of R₁ to R₅ being iodine.

### BRIEF DESCRIPTION OF THE DRAWINGS

Features will be apparent to those of skill in the art by describing in detail exemplary embodiments with reference to the attached drawings in which:

FIG. 1 is a diagram for explaining an EUV lithography apparatus;

FIG. 2 is a graph showing EUV absorption cross sections of carbon (C), hydrogen (H), oxygen (O) and sulfur (S) and halogen elements such as fluorine (F), chlorine (Cl), bromine (Br), and iodine (I);

FIG. 3A, FIG. 4A, FIG. 5A and FIG. 6A are plan views of stages in a photolithography process according to embodiments; and

FIG. 3B, FIG. 4B, FIG. 5B and FIG. 6B are cross sectional views taken along lines A-A′ of FIG. 3A, FIG. 4A, FIG. 5A and FIG. 6A.

### DETAILED DESCRIPTION

In the description, the term “substituted or unsubstituted” may mean substituted or unsubstituted with one or more substituents selected from the group consisting of a hydrogen atom, a halogen atom, an alkyl group, a hydroxyl group, an alkoxy group, an ether group, an alkenyl group, an aryl group, a hydrocarbon ring group and a heterocyclic group.

In the description, the halogen atom may include fluorine, chlorine, iodine, and/or bromine.

In the description, the alkyl group may be a linear alkyl group, a branched alkyl group, or a cyclic alkyl group. Unless otherwise specified, the carbon number of the alkyl group may be 1 to 10 carbon atoms. Examples of the alkyl group may include a methyl group and an ethyl group.

In the chemical formulae in the description, if a chemical bond is not drawn at a position requiring a chemical bond, it may mean that a hydrogen atom is bonded at the position, unless otherwise defined.

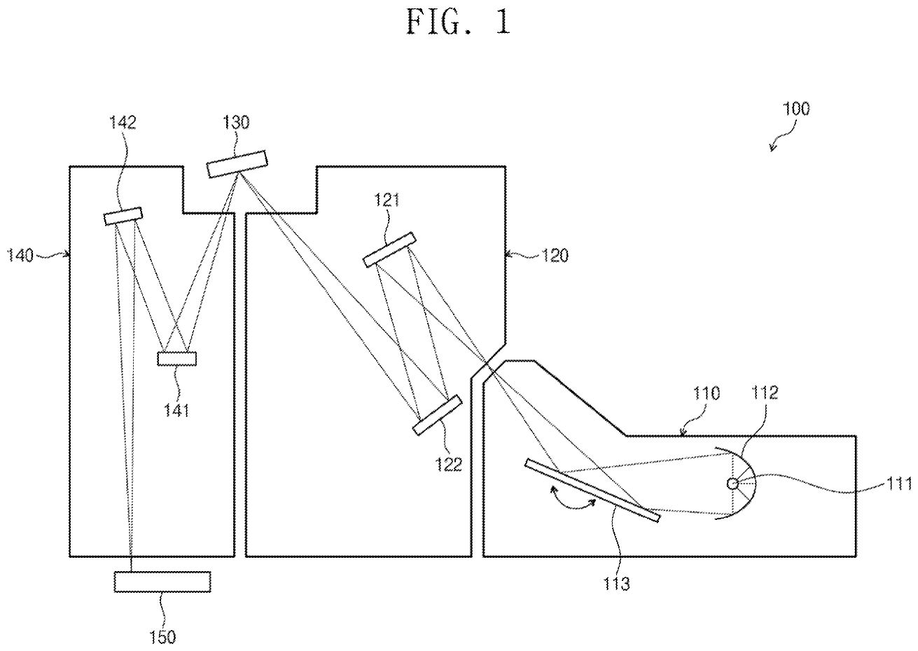

FIG. 1 is a diagram for explaining an extreme ultraviolet (EUV) lithography apparatus.

Referring to FIG. 1, an EUV lithography apparatus 100 may include a beam shaping system or beam shaper 110, an illumination system or illuminator 120, a photo mask 130, and a projection system or projector 140. The beam shaper 110, the illuminator 120, and the projector 140 may be in each housing. In an implementation, the beam shaper 110 may be partially or as a whole integrated in the illuminator 120.

The beam shaper 110 may include a light source 111, a collector 112 and a monochromator 113.

The light source 111 may be a laser plasma source, a gas discharge source, or a synchrotron radiation source. Light emitted from the light source 111 may have a wavelength in a range of about 5 nm to about 20 nm. The illuminator 120 and the projector 140 may be composed or designed to operate in the wavelength range. EUV emitted from the light source 111 may be concentrated by the collector 112. The monochromator 113 may filter light having an undesired wavelength.

EUV of which wavelength and space distribution are controlled in the beam shaper 110 may be introduced into the illuminator 120. In an implementation, as illustrated in FIG. 1, the illuminator 120 may include two mirrors 121 and 122. Each of the mirrors 121 and 122 may be a multilayer mirror.

By the mirrors 121 and 122 in the illuminator 120, EUV may be incident toward the photo mask 130. In an implementation, the photo mask 130 may include certain patterns to be transcribed onto a substrate 150. The incident EUV may be reflected by the certain patterns of the photo mask 130. The reflected EUV may be projected through the projector 140 on the substrate 150 coated with a photoresist composition thereon. In an implementation, the photo mask 140 may be formed so as to reflect EUV.

The projector 140 may irradiate the EUV reflected from the photo mask 130 to the substrate 150 coated with the photoresist composition thereon. By the EUV irradiated on the substrate 150, the image of a pattern structure may be made in the photoresist composition. In an implementation, as illustrated in FIG. 1, the projector 140 may include two mirrors 141 and 142. Each of the mirrors 141 and 142 may be a multilayer mirror.

Hereinafter, the photoresist composition according to embodiments will be explained in detail. The photoresist composition may be used for forming patterns or for manufacturing a semiconductor device. In an implementation, the photoresist composition may be used in a patterning process for manufacturing a semiconductor device. The photoresist composition may be a photoresist composition for EUV or a photoresist composition for an electron beam. EUV may mean ultraviolet radiation having a wavelength of about 10 nm to about 124 nm, e.g., about 13.0 nm to about 13.9 nm, or about 13.4 nm to about 13.6 nm. EUV may mean light having energy of about 6.21 eV to about 124 eV, e.g., about 90 eV to about 95 eV. The photoresist composition according to embodiments may be a chemical amplification type (CAR type) photoresist composition.

The photoresist composition according to an embodiment may include, e.g., a photosensitive resin, a photo-acid generator (PAG), a photo decomposable quencher (PDQ), an additive, and a solvent.

In an implementation, the photosensitive resin may include a polymer represented by the following Formula 1A.

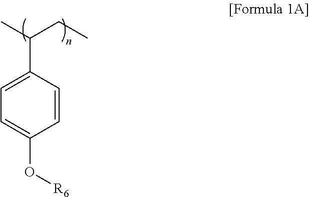

In Formula 1A, R₆ may be, e.g., hydrogen or an alkyl group having 1 to 15 carbon atoms. “n” may be an integer of, e.g., 10 to 1,000,000.

In an implementation, the photosensitive resin may include a polymer represented by the following Formula 1B.

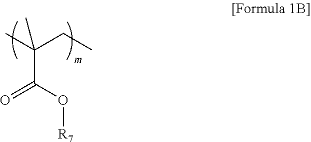

In Formula 1B, R₆ may be, e.g., hydrogen or an alkyl group having 1 to 15 carbon atoms. “m” may be an integer of, e.g., 10 to 1,000,000.

In an implementation, the photosensitive resin may include a block copolymer represented by the following Formula 1C.

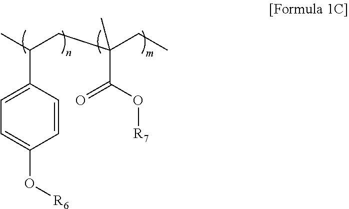

In Formula 1C, R₆ and R₇ may each independently be, e.g., hydrogen or an alkyl group having 1 to 15 carbon atoms. “n” and “m” may each independently be, e.g., an integer of 10 to 1,000,000.

In an implementation, the photosensitive resin may include a block copolymer represented by the following Formula 1D.

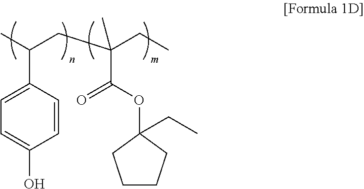

In Formula 1D, “n” and “m” may each independently be, e.g., an integer of 10 to 1,000,000.

The photo-acid generator may produce hydrogen ions in response to an exposing process, which will be described in greater detail below. The photo-acid generator may include a material which may produce an acid by or in response to light. In an implementation, the photo-acid generator may include a cation represented by the following Formula 2A and an anion represented by the following Formula 2B.

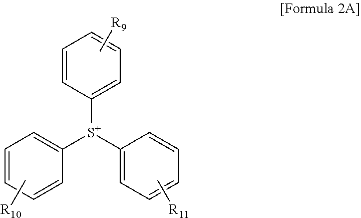

In Formula 2B, R₉ to R₁₁ may each independently be, e.g., hydrogen, a halogen, a substituted or unsubstituted carboxyl group, a substituted or unsubstituted alkoxy group, or an alkyl group having 1 to 15 carbon atoms.

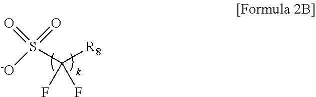

In Formula 2B, R₈ may be, e.g., hydrogen, a halogen, a substituted or unsubstituted carboxyl group, a substituted or unsubstituted alkoxy group, or an alkyl group having 1 to 15 carbon atoms. “k” may be an integer of 1 to 20. The photo-acid generator composed of the cation of Formula 2A and the anion of Formula 2B may be referred to as triphenylsulfonium triflate (TPS-Tf).

As a particular embodiment of Formula 2B, the photo-acid generator may include an anion represented by the following Formula 2C.

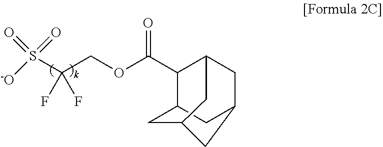

In an implementation, the photo-acid generator may include a cation represented by the following Formula 2D and an anion represented by Formula 2B above.

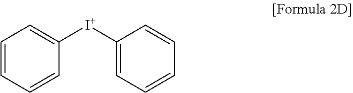 [SMILES: c1ccc([I+]c2ccccc2)cc1]

The photo-acid generator composed of the cation of Formula 2D and the anion of Formula 2B may be referred to as diphenyliodonium triflate (DPT-Tf).

The photo decomposable quencher (hereinafter, quencher) may include a base material. In an implementation, the quencher may include a cation represented by the following Formula 2A and an anion represented by one of the following Formula 3A or Formula 3B.

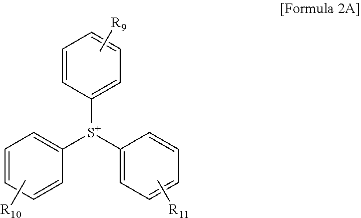

In Formula 2A, R₉ to R₁₁ may each independently be, e.g., hydrogen, a halogen, a substituted or unsubstituted carboxyl group, a substituted or unsubstituted alkoxy group, or an alkyl group having 1 to 15 carbon atoms.

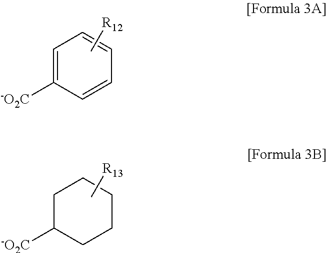

In Formula 3A and Formula 3B, R₁₂ and R₁₃ may each independently be, e.g., hydrogen, a halogen, a substituted or unsubstituted carboxyl group, a substituted or unsubstituted alkoxy group, or an alkyl group having 1 to 15 carbon atoms. The photo-acid generator composed of the cation of Formula 2A and the anion of Formula 3A or Formula 3B may be referred to as triphenylsulfonium carboxylate.

In an implementation, the quencher may include an amine, and the amine may be a tertiary amine. In an implementation, the carbon number of the tertiary amine may be, e.g., 10 to 100. The quencher may include, e.g., a material represented by Formula 3C and/or a material represented by Formula 3D. The material represented by Formula 3C may be tri(n-octyl)amine. The material represented by Formula 3D may be 1,8-diazabicyclo[5,4,0]undec-7-ene (DBU).

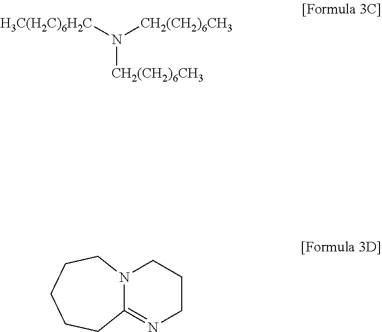

In an implementation, the solvent may include, e.g., ethyl cellosolve acetate (ECA), ethyl lactate (EL), propylene glycol monomethyl ether acetate (PGMEA), propylene glycol methyl ether (PGME), N-butyl acetate (n-BA), 2-heptanone (MAK), methyl ethyl ketone (MEK), N,N-dimethyl formamide (DMF), N-methylpyrrolidone (NMP), ethyl 3-ethoxypropionate (EEP), methyl 3-methoxypropionate (MMP), ethyl pyruvate (EP), or isopropyl alcohol (IPA).

Hereinafter, an iodophenol compound that is an additive according to embodiments will be explained in more detail.

The additive may include a compound represented by the following Formula 4A.

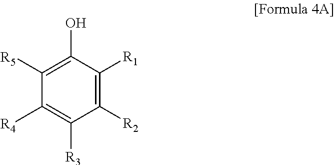

In Formula 4A, R₁ to R₅ may each independently be, e.g., hydrogen, a halogen, an alkyl group having 1 to 15 carbon atoms, or an aryl group having 6 to 18 carbon atoms. Each of the alkyl group and the aryl group may be substituted with a halogen or unsubstituted. In an implementation, at least one among R₁ to R₅ may be iodine (I). In an implementation, the compound of Formula 4A may be a compound obtained by substituting at least one hydrogen atom of phenol with iodine (I). In an implementation, at least one among R₁ to R₅ may be iodine (I), and the others may be hydrogen.

In an implementation, the additive (i.e., iodophenol compound) may include a compound represented by one of the following Formula 4B to Formula 4F.

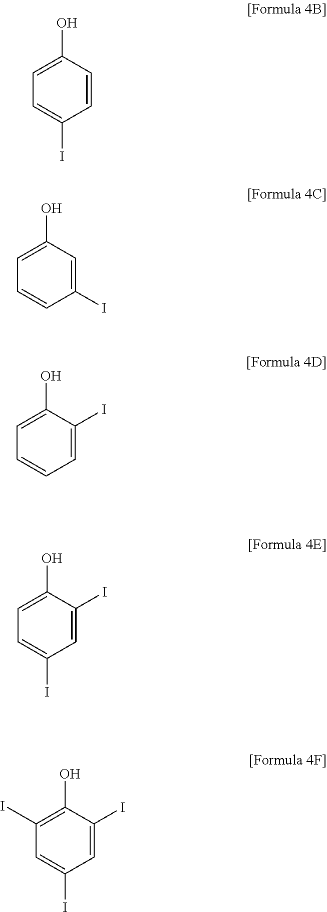

The iodophenol compound is an additive and may be a component of the photoresist composition, e.g., may be a component of a mixture of components forming the composition. The iodophenol compound may not react chemically with another material in the photoresist composition and may be present solely as one molecular shape.

If the iodophenol compound were to be used as a unit composing a polymer that is a photosensitive resin, the physical properties of the photosensitive resin required in the photoresist composition may not be satisfied. Further, the iodophenol compound may not be used as the photo-acid generator or the quencher due to the molecular structure and properties thereof. In an implementation, the photoresist composition according to embodiments may include the iodophenol compound as an additive to be mixed in the composition to help increase EUV absorption.

The iodophenol compound may have a molecular structure similar to the polymer of Formula 1A (e.g., polyhydroxystyrene (PHS)) of the photosensitive resin. In an implementation, the iodophenol compound may be uniformly dispersed between the photosensitive resin polymers. In an implementation, the iodophenol compound may be uniformly mixed in the photoresist composition.

During the exposing process of the photoresist layer, the photosensitive resin may absorb light (i.e., EUV) and emit secondary-electrons. The secondary-electrons may move and be trapped by the photo-acid generator. The photo-acid generator may decompose the transferred secondary-electrons and produce hydrogen ions (W).

If the EUV absorption of the photoresist composition for EUV increases, the production ratio of the secondary-electrons and the production ratio of an acid (i.e., H⁺) may increase. In an implementation, if the EUV absorption of the photoresist composition for EUV increases, the degrees of precision and accuracy of a photolithography process may be improved.

In an implementation, the photosensitive resin, photo-acid generator, quencher, and solvent in the photoresist composition, described above, may be composed of only carbon (C), hydrogen (H), oxygen (O), and sulfur (S). The carbon (C), hydrogen (H), oxygen (O), and sulfur (S) may have a drawback of low EUV absorption.

The additive according to an embodiment, e.g., the iodophenol compound, may help increase the EUV absorption of the photoresist composition. The iodine (I) may have higher EUV absorption than the aforementioned carbon (C), hydrogen (H), oxygen (O), and sulfur (S). The iodine (I) may also exhibit higher EUV absorption than other halogen atoms (e.g., bromine (Br), fluorine (F), etc.). The iodophenol compound according to an embodiment may absorb EUV efficiently through iodine (I) in the molecule.

In an implementation, the photoresist composition may include, e.g., about 0.5 wt % to about 5 wt % of the photosensitive resin, about 0.01 wt % to about 3 wt % of the photo-acid generator, about 0.01 wt % to about 3 wt % of the quencher, about 0.1 wt % to about 1 wt % of the additive, and a remaining or balance amount of the solvent. (e.g., based on a total weight of the composition)

The iodophenol compound additive may have improved or increased EUV absorption properties. The EUV absorption properties may be evaluated by an EUV absorption coefficient.

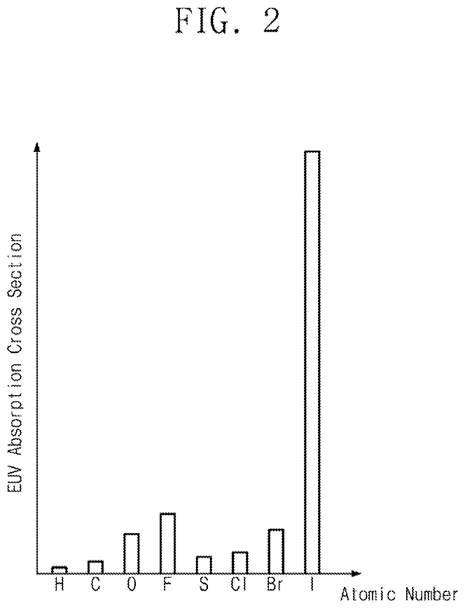

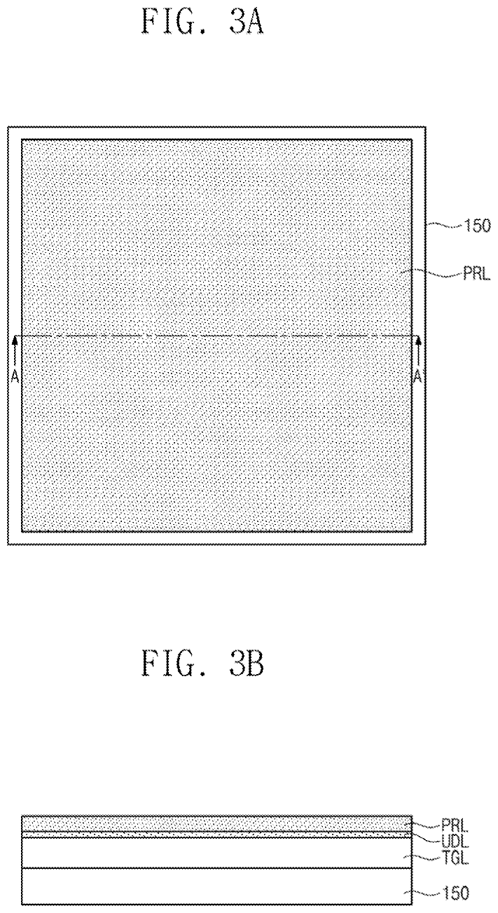

FIG. 2 is a graph showing EUV absorption cross sections of carbon (C), hydrogen (H), oxygen (O), sulfur (S), and halogen elements (fluorine (F), chlorine (Cl), bromine (Br), and iodine (I)). The EUV absorption cross section may be a value obtained by dividing an EUV absorption coefficient of each element by the atomic number density thereof.

Referring to FIG. 2, it may be seen that iodine (I) has very high EUV absorption relative to the elements composing the photoresist composition, e.g., carbon (C), hydrogen (H), oxygen (O), and sulfur (S). In addition, it may be seen that iodine (I) has very high EUV absorption relative to each of other halogen elements, e.g., fluorine (F), chlorine (Cl), and bromine (Br). For example, it may be seen that the photoresist composition that includes iodine (I) may help increase the EUV absorption.

Hereinafter, a photolithography process and a method of manufacturing a semiconductor device using the photoresist composition according to an embodiment will be explained.

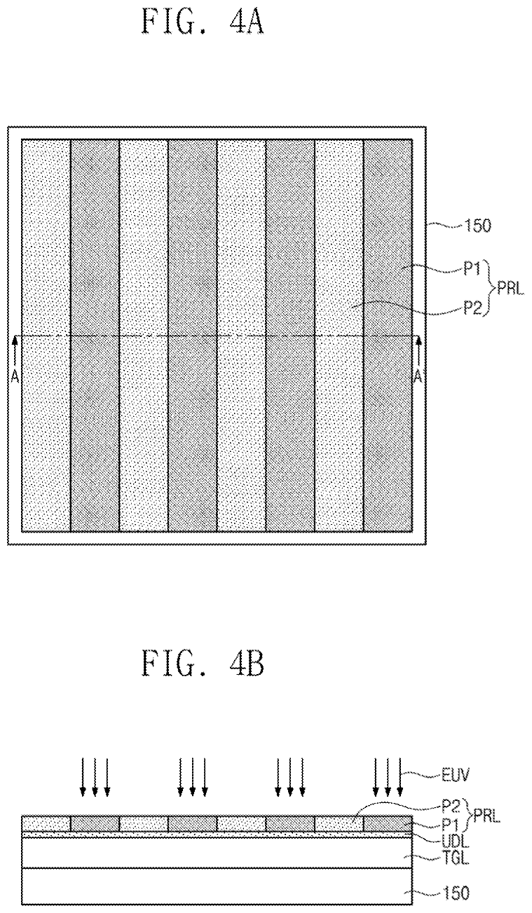

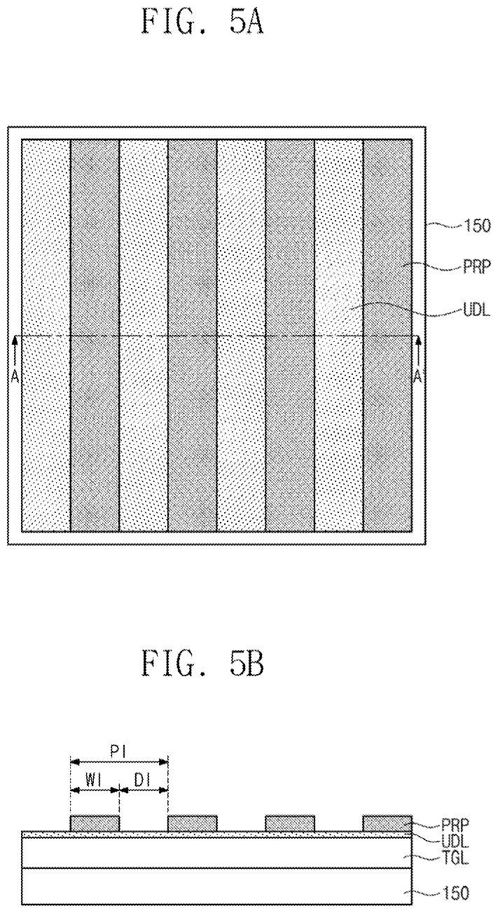

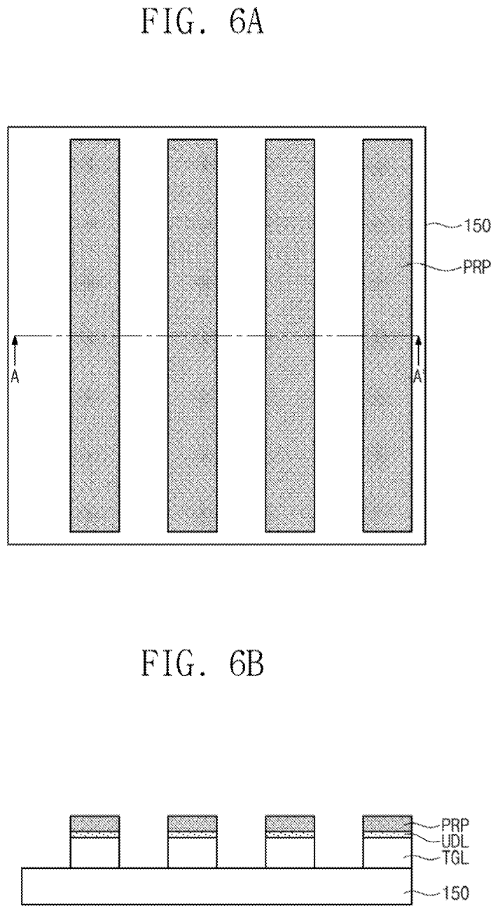

FIG. 3A, FIG. 4A, FIG. 5A and FIG. 6A are plan views of stages in a photolithography process according to embodiments. FIG. 3B, FIG. 4B, FIG. 5B and FIG. 6B are cross sections taken along lines A-A′ of FIG. 3A, FIG. 4A, FIG. 5A and FIG. 6A.

Referring to FIG. 3A and FIG. 3B, a substrate 150 may be prepared. The substrate 150 may be a semiconductor wafer such as a silicon wafer. On the substrate 150, a target layer TGL, an underlayer UDL, and a photoresist layer PRL may be formed in order.

The target layer TGL may include, e.g., a semiconductor material, a conductive material and an insulating material, or combinations thereof. The target layer TGL may be a target layer to be etched, or a hard mask. In an implementation, one or more layers may be further provided between the substrate 150 and the target layer TGL.

The underlayer UDL may be a coating layer coated on the target layer TGL. The underlayer UDL may play the function of an adhesive layer attaching the photoresist layer PRL onto the target layer TGL. The underlayer UDL may include a polymer resin. The underlayer UDL may further include the above-described additive from the photoresist composition according to an embodiment, i.e., the iodophenol compound. In this case, the EUV absorption of the underlayer UDL may also be increased.

In an implementation, the underlayer UDL may selectively or optionally include the iodophenol compound. In an implementation, the photoresist layer PRL may essentially include the iodophenol compound as the additive to help increase direct EUV absorption.

The photoresist layer PRL may be formed by applying the above-described photoresist composition on the underlayer UDL. The formation of the photoresist layer PRL may include applying the photoresist composition on the underlayer UDL by spin coating.

A heat treatment process may be performed on the photoresist layer PRL. The heat treatment process may correspond to the baking process of the photoresist layer PRL. Through the baking process, solvents in the photoresist composition may be removed.

Referring to FIG. 4A and FIG. 4B, the photoresist layer PRL may be exposed to EUV. Through the EUV lithography apparatus explained referring to FIG. 1, the photoresist layer PRL may be exposed to EUV. By the photo mask 130 of FIG. 1, EUV may be selectively irradiated on the first parts P1 of the photoresist layer PRL. The second parts P2 of the photoresist layer PRL may be unexposed to EUV.

When the photoresist layer PRL is exposed to EUV, the photo sensitive resin may emit secondary-electrons as explained above. If the production ratio of the secondary-electrons increases, the first parts P1 may be formed accurately and rapidly. The photoresist layer PRL according to an embodiment may include an iodophenol compound as an additive, and a high EUV absorption may be attained. Accordingly, the production ratio of the secondary-electrons may be improved.

The second parts P2 of the photoresist layer PRL are not exposed to EUV, and the chemical structure of the compounds in the second parts P2 may not be changed. Accordingly, after completing the EUV irradiation, the first parts P1 and the second parts P2 of the photoresist layer PRL may have different chemical structures. For example, the first parts P1 and the second parts P2 of the photoresist layer PRL may have different solubility with respect to a developing solution.

Referring to FIG. 5A and FIG. 5B, the second parts P2 of the photoresist layer PRL may be dissolved by the developing solution and may be selectively removed. The first parts P1 of the photoresist layer PRL may be insoluble in the developing solution and remain intact. The remaining first parts P1 may form photoresist patterns PRP. For example, the photoresist patterns PRP may be formed by performing exposing and developing processes on the photoresist layer PRL.

In an implementation, the photoresist patterns PRP may be formed into line shapes which extend lengthwise in parallel in one direction. The photoresist patterns PRP may be formed with a certain pitch PI. The photoresist pattern PRP may have a line width WI. A pair of adjacent photoresist patterns PRP may be separated with a certain distance DI from each other. The pitch PI of the photoresist patterns PRP may be the sum of the line width WI and the distance DI.

In the photolithography process, the minimum distance DI between the photoresist patterns PRP under a certain pitch PI may be defined as minimum critical dimension (minimum CD). If the distance DI between the photoresist patterns PRP is a smaller value than the minimum CD, the photoresist patterns PRP may not be separated from each other but may be agglomerated to form one lump. Accordingly, with the decrease of the minimum CD, the degree of precision of the photolithography process may increase.

The planar shape of the photoresist patterns PRP shown in FIG. 5A is an illustration. The planar shape of the photoresist patterns PRP according to an embodiment may have various shapes such as a zigzag shape, a honeycomb shape, and a circular shape.

Referring to FIG. 6A and FIG. 6B, an etching process may be performed with respect to the substrate 150 by using the photoresist patterns PRP as an etching mask, to etch the underlayer UDL and the target layer TGL in order. With this process, the target layer TGL may be patterned by the photoresist patterns PRP.

### Experimental Examples

Photoresist compositions according to Example 1, Example 2, and Example 3 were prepared using the iodophenol compounds of Formula 4B, Formula 4C and Formula 4F, respectively, as additives.

Photoresist compositions according to Comparative Example 1, Comparative Example 2, and Comparative Example 3 were prepared using the compound of the following Formula 5A, the compound of the following Formula 5B, and the compound of the following Formula 5C, respectively, as additives.

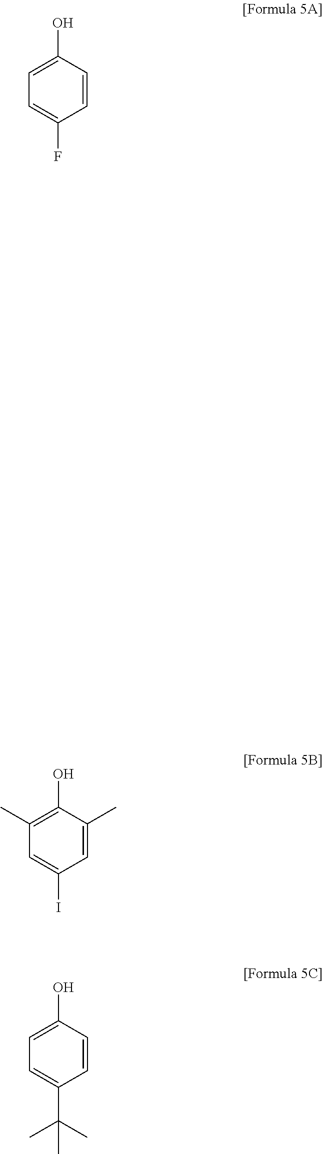

A photoresist composition (Comparative Example 4) without an additive was prepared as a control group.

Based on the photoresist compositions thus prepared, the photolithography process according to FIG. 3A to FIG. 5B was performed to form photoresist patterns. The minimum CD of the photoresist patterns thus formed was measured. The pitch between the photoresist patterns was about 36 nm. The results are shown in Table 1 below.

TABLE 1

| | | Minimum CD |
|---|---|---|
| Composition | Additive | (nm) |
| Example 1 | 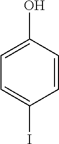 | 13.0 |
| Example 2 | 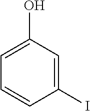 | 12.8 |
| Example 3 | 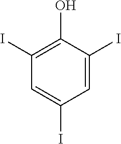 | 12.6 |
| Comparative Example 1 | 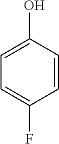 | 14.1 |
| Comparative Example 2 | 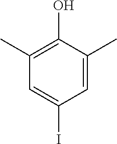 | 13.9 |
| Comparative Example 3 | 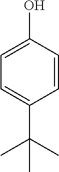 | 14.0 |
| Comparative Example 4 | Omitted | 13.8 |

Referring to Table 1, it may be seen that the photoresist compositions according to Example 1, Example 2, and Example 3 showed decreased minimum CD by about 1 nm, when compared with the photoresist composition of Comparative Example 4 that was a control group. Example 3, in which more iodine (I) was included in the additive, had the lowest minimum CD. If more hydrogen atoms of phenol are substituted or replaced with iodine (I), the EUV absorption may increase.

It may be seen that the photoresist compositions of Comparative Example 1 and Comparative Example 3 showed no change of the minimum CD, when compared with the photoresist composition of Comparative Example 4. In other words, it may be seen that when iodine (I) is not included in the phenol additive, no particular effects on the EUV absorption were observed. Further, it may be seen that when fluorine (F) is used instead of iodine (I), there are no or insignificant beneficial effects on the EUV absorption (see Comparative Example 1).

Additionally, it may be seen that the photoresist composition of Comparative Example 2 showed little change of the minimum CD when compared with the photoresist composition of Comparative Example 4. It may be seen that if additional functional groups (for example, alkyl group) in addition to iodine (I) are substituted or included in the phenol, the EUV absorption may be inhibited.

By way of summation and review, with the increase of the integration degree of semiconductor devices, finer patterning may be required during the manufacturing process of the semiconductor devices. The patterning of a target layer to be etched may be performed by an exposing process and a developing process using a photoresist layer.

One or more embodiments may provide a photoresist composition for use with extreme ultraviolet radiation (EUV).

One or more embodiments may provide a photoresist composition which may improve the degrees of precision and accuracy of a photolithography process using EUV.

According to an embodiment, the photoresist composition may have high EUV absorption. Accordingly, the degrees of precision and accuracy of a photolithography process may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photolithography method, comprising:
applying a composition on a substrate to form a photoresist layer;
performing an exposing process using extreme ultraviolet radiation (EUV) on the photoresist layer; and
developing the photoresist layer to form photoresist patterns,
wherein:
the composition includes a photosensitive resin, a photo-acid generator, a photo decomposable quencher, an additive, and a solvent, and
the additive is a compound represented by the following Formula 4A: 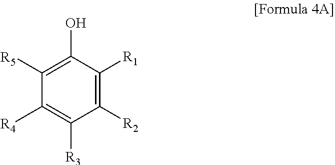
in Formula 4A, R₁ to R₅ are each independently hydrogen or iodine, at least one of R₁ to R₅ being iodine.

2. The photolithography method as claimed in claim 1, wherein the photosensitive resin includes a polymer of the following Formula 1A, a polymer of the following Formula 1B, or a polymer of the following Formula 1C, 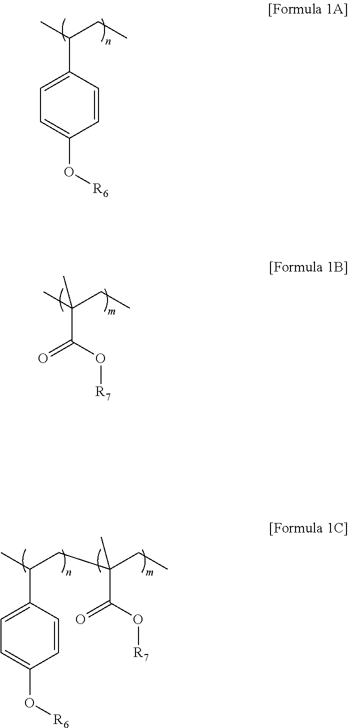
wherein, in Formulae 1A to 1C,
R₆ and R₇ are each independently hydrogen or an alkyl group having 1 to 15 carbon atoms, and
“n” and “m” are each independently an integer of 10 to 1,000,000.

3. The photolithography method as claimed in claim 1, wherein the photo-acid generator includes a cation represented by the following Formula 2A and an anion represented by the following Formula 2B, 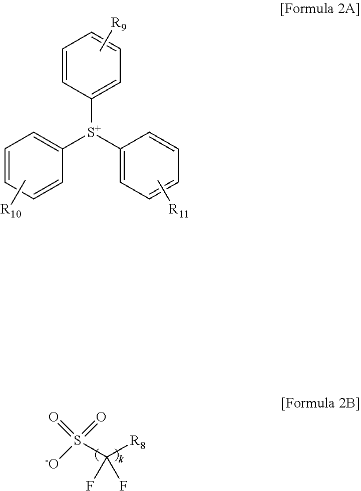
wherein, in Formulae 2A and 2B,
R₈, R₉, R₁₀ and R₁₁ are each independently hydrogen, a halogen, a substituted or unsubstituted carboxyl group, a substituted or unsubstituted alkoxy group, or an alkyl group having 1 to 15 carbon atoms, and
“k” is an integer of 1 to 20.

4. The photolithography method as claimed in claim 1, wherein the photo decomposable quencher includes a cation represented by the following Formula 2A and an anion represented by the following Formula 3A or Formula 3B, 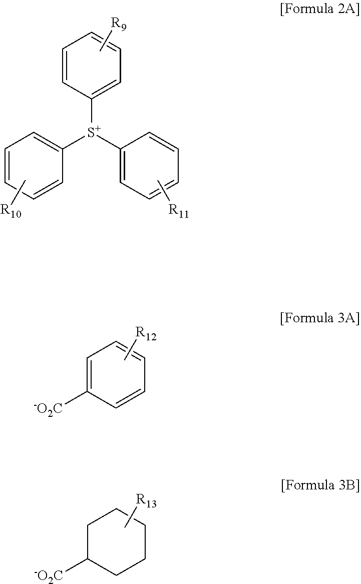
wherein, in Formulae 2A, 3A, and 3B, R₉, R₁₀, R₁₁, R₁₂ and R₁₃ are each independently hydrogen, a halogen, a substituted or unsubstituted carboxyl group, a substituted or unsubstituted alkoxy group, or an alkyl group having 1 to 15 carbon atoms.

5. The photolithography method as claimed in claim 1, wherein the additive is uniformly mixed in the composition.

6. The photolithography method as claimed in claim 1, wherein the solvent includes ethyl cellosolve acetate, ethyl lactate, propylene glycol monomethyl ether acetate, propylene glycol methyl ether, N-butyl acetate, 2-heptanone, methyl ethyl ketone, N,N-dimethyl formamide, N-methylpyrrolidone, ethyl 3-ethoxypropionate, methyl 3-methoxypropionate, ethyl pyruvate, or isopropyl alcohol.

7. The photolithography method as claimed in claim 1, wherein, in the composition:
an amount of the photosensitive resin is about 0.5 wt % to about 5 wt %,
an amount of the photo-acid generator is about 0.01 wt % to about 3 wt %,
an amount of the photo decomposable quencher is about 0.01 wt % to about 3 wt %, and
an amount of the additive is about 0.1 wt % to about 1 wt %, all wt % being based on a total weight of the composition.

8. The photolithography method as claimed in claim 1, further comprising forming an underlayer under the photoresist layer.

9. The photolithography method as claimed in claim 8, wherein the underlayer includes a compound represented by Formula 4A as an additive.

10. The photolithography method as claimed in claim 1, further comprising performing a heat treatment process on the photoresist layer prior to performing the exposing process.

11. A method of manufacturing a semiconductor device, the method comprising:
forming a target layer on a substrate;
applying a composition on the target layer to form a photoresist layer;
performing an exposing process using extreme ultraviolet radiation (EUV) on the photoresist layer;
developing the photoresist layer to form photoresist patterns; and
performing an etching process for patterning the target layer using the photoresist patterns as a mask,
wherein:
the composition includes a compound represented by the following Formula 4A as an additive, 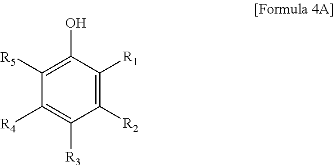
in Formula 4A, R₁ to R₅ are each independently hydrogen or iodine, at least one of R₁ to R₅ being iodine.

12. The method of manufacturing a semiconductor device as claimed in claim 11, wherein:
the composition further includes a photosensitive resin,
the photosensitive resin includes a polymer of the following Formula 1A, a polymer of the following Formula 1B, or a polymer of the following Formula 1C, 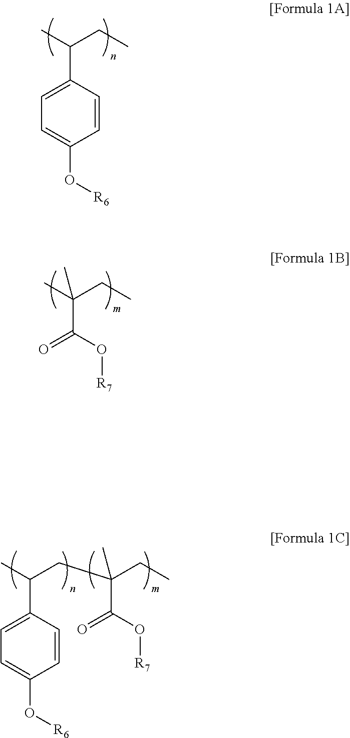
in Formulae 1A to 1C,
R₆ and R₇ are each independently hydrogen or an alkyl group having 1 to 15 carbon atoms, and
“n” and “m” are each independently an integer of 10 to 1,000,000.

13. The method of manufacturing a semiconductor device as claimed in claim 11, wherein:
the composition further includes a photo-acid generator, and
the photo-acid generator includes a cation represented by the following Formula 2A and an anion represented by the following Formula 2B: 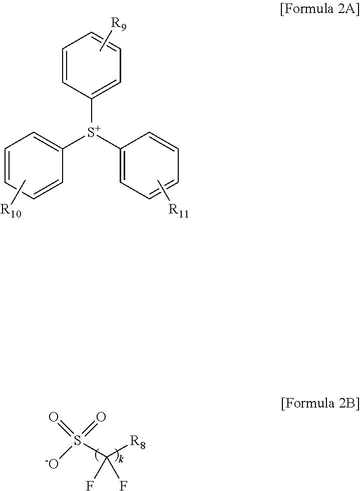
In Formulae 2A and 2B,
R₈, R₉, R₁₀ and R₁₁ are each independently hydrogen, a halogen, a substituted or unsubstituted carboxyl group, a substituted or unsubstituted alkoxy group, or an alkyl group having 1 to 15 carbon atoms, and
“k” is an integer of 1 to 20.

14. The method of manufacturing a semiconductor device as claimed in claim 11, wherein:
the composition further includes a photo decomposable quencher, and
the photo decomposable quencher includes a cation represented by the following Formula 2A and an anion represented by the following Formula 3A or Formula 3B: 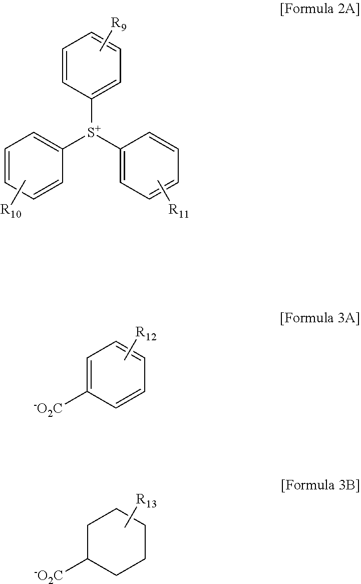
in Formulae 2A, 3A, and 3B, R₉, R₁₀, R₁₁, R₁₂ and R₁₃ are each independently hydrogen, a halogen, a substituted or unsubstituted carboxyl group, a substituted or unsubstituted alkoxy group, or an alkyl group having 1 to 15 carbon atoms.

15. The method of manufacturing a semiconductor device as claimed in claim 11, wherein the additive is a component which is uniformly mixed in the composition.

16. The method of manufacturing a semiconductor device as claimed in claim 11, wherein the solvent includes ethyl cellosolve acetate, ethyl lactate, propylene glycol monomethyl ether acetate, propylene glycol methyl ether, N-butyl acetate, 2-heptanone, methyl ethyl ketone, N,N-dimethyl formamide, N-methylpyrrolidone, ethyl 3-ethoxypropionate, methyl 3-methoxypropionate, ethyl pyruvate, or isopropyl alcohol.

17. The method of manufacturing a semiconductor device as claimed in claim 11, further comprising forming an underlayer between the photoresist layer and the target layer.

18. The method of manufacturing a semiconductor device as claimed in claim 17, wherein the underlayer further includes a compound represented by Formula 4A as an additive.

19. The method of manufacturing a semiconductor device as claimed in claim 11, further comprising performing a heat treatment process on the photoresist layer prior to performing the exposing process.

20. The method of manufacturing a semiconductor device as claimed in claim 11, wherein a minimum critical dimension between the photoresist patterns is less than about 13.5 nm.
